(19) United States
(12) Patent Application Publication
(10) Pub. No.: US 2014/0014398 A1
(43) Pub. Date: Jan. 16, 2014

(54) CORELESS SUBTRATE AND METHOD OF MANUFACTURING THE SAME

(71) Applicant: SAMSUNG ELECTRO-MECHANICS CO., LTD, Gyunggi-do (KR)

(72) Inventors: Ki Hwan Kim, Gyunggi-do (KR); Myung Sam Kang, Gyunggi-do (KR); Da Hee Kim, Gyunggi-do (KR); Yoong Oh, Gyunggi-do (KR)

(73) Assignee: SAMSUNG ELECTRO-MECHANICS CO., LTD., Gyunggi-do (KE)

(21) Appl. No.: 13/650,050

(22) Filed: Oct. 11, 2012

(30) Foreign Application Priority Data
Jul. 13, 2012 (KR) 10-2012-0076645

(51) Int. Cl. H05K 1/00; B32B 37/14; B32B 38/10

(52) U.S. Cl. 174/250; 156/247

(57) ABSTRACT

Disclosed herein is a coreless substrate according to a preferred embodiment of the present invention, the coreless substrate including: a first insulating layer including at least one first pillar; a plurality of insulating layers laminated in a direction of one surface or both surfaces of the first insulating layer, including at least one circuit layer and at least one another pillar connected to the circuit layer; and a plurality of outermost circuit layers contacting an outermost pillar disposed on an outermost insulating layer among the plurality of insulating layers.

### CROSS REFERENCE TO RELATED APPLICATION

This application claims the benefit of Korean Patent Application No. 10-2012-0076645, filed on Jul. 13, 2012, entitled “Coreless Substrate And Method Of Manufacturing The Same”, which is hereby incorporated by reference in its entirety into this application.

### BACKGROUND OF THE INVENTION

1. Technical Field

The present invention relates to a coreless substrate and a method of manufacturing the same.

2. Description of the Related Art

Generally, a printed circuit board is implemented by wiring a copper clad on one surface or both surfaces of a board made of various kinds of thermosetting synthetic resins, fixing IC or electronic components on the board, and implementing electrical wirings therebetween and then, coating the electrical wirings with an insulator.

Recently, with the development of electronic industries, a demand for multi-functional and light and small electronic components has been rapidly increased. Accordingly, there is a need to increase a wiring density of a printed circuit board on which the electronic components are mounted and reduce a thickness thereof.

In particular, in order to cope with the thinness of the printed circuit board, a coreless substrate with the reduced thickness and signal processing time by removing a core substrate has been spotlighted. In case of the coreless substrate, since the core substrate is removed, a carrier member serving as a support during a manufacturing process is required. An upper substrate and a lower substrate are separated from each other by forming a buildup layer including circuit layers and insulating layers on both surfaces of the carrier member according to a method of manufacturing a substrate of the prior art and removing the carrier member, such that the coreless substrate is completed.

As described Korean Patent Laid-Open Publication No. 2010-0043547 (Laid-Open Publication: Apr. 29, 2010), the method of manufacturing a coreless substrate of the prior art performs a laser direct ablation (LDA) method for forming opening parts on an insulating layer as a previous stage for forming vias for electrical connection of each buildup layer.

However, the LDA method may cause an increase in machining time due to a limitation of a laser spot size when a size of the opening part is large.

Further, the method of manufacturing a coreless substrate according to the prior art need to perform laser machining several times, thereby increasing complexity and costs of process.

### SUMMARY OF THE INVENTION

The present invention has been made in an effort to provide a coreless substrate including a plurality of pillars forming electrical connection of buildup layers by using a dry film.

In addition, the present invention has been made in an effort to provide a method of manufacturing a coreless substrate including a plurality of pillars forming electrical connection of buildup layers by using a dry film.

According to a preferred embodiment of the present invention, there is provided a coreless substrate, including: a first insulating layer including at least one first pillar; a plurality of insulating layers laminated in a direction of one surface or both surfaces of the first insulating layer, including at least one circuit layer and at least one another pillar connected to the circuit layer; and a plurality of outermost circuit layers contacting an outermost pillar disposed on an outermost insulating layer among the plurality of insulating layers.

The circuit layer may be symmetrically disposed in a direction of both surfaces of the first pillar based on the first pillar.

The circuit layer and another pillar may be sequentially repeatedly disposed in an order of the circuit layer contacting the first pillar and the pillar connected to the circuit layer.

According to another preferred embodiment of the present invention, there is provided a method of manufacturing a coreless substrate, including: (A) providing at least one barrier plate structure sequentially including a first circuit layer and a first pillar in one direction of a barrier plate; (B) compressing the barrier plate structure to a first insulating layer disposed on one surface or both surfaces of a carrier substrate, corresponding to the first pillar; (C) removing the barrier plate and forming a second pillar connected to the first circuit layer; (D) forming a second insulating layer in which the second pillar is buried; (E) separating the carrier substrate; (F) planarizing the first insulating layer and the second insulating layer; and (G) laminating a plurality of other insulating layers sequentially including another circuit layer and another pillar on an outer surface of the second insulating layer exposing the second pillar or an outer surface of the first insulating layer exposing the first pillar.

Step (A) may include: (A-1) laminating a dry film on one surface of the barrier plate and exposing and developing the laminated dry film to form a dry film pattern having a plurality of opening parts; (A-2) filling the dry film pattern with copper to form a circuit layer; (A-3) forming a dry film pattern for forming a pillar on a surface of the barrier plate on which the circuit layer is disposed; and (A-4) filling the dry film pattern for forming a pillar with copper and peeling off the dry film pattern for forming a pillar to form the first pillar.

Step (C) may include: (C-1) removing the barrier plate by an etching method or a chemical mechanical polishing method; (C-2) forming a dry film pattern for a second pillar on the first insulating layer; and (C-3) filling the dry film pattern for the second pillar with copper and peeling off the dry film pattern for the second pillar to form the second pillar.

In step (D), the second insulating layer in an uncured film state may be compressed to the second pillar using a laminator.

In step (E), the carrier substrate may include an insulating plate and at least one copper clad laminated on one surface or both surfaces of the insulating plate, and the carrier substrate may be routed so as to be separated.

Step (G) may include: (G-1) forming the another circuit layers on the outer surface of the second insulating layer exposing the second pillar or the outer surface of the first insulating layer exposing the first pillar; (G-2) forming another dry film pattern for forming a pillar on the another circuit layer; (G-3) filling the another dry film pattern for forming a pillar with copper to form the another filler connected to the another circuit layer; (G-4) peeling off the another dry film pattern for forming a pillar; (G-5) laminating the another insulating layer corresponding to the another pillar by using the laminator; and (G-6) planarzing the another insulating layer so as to expose the another pillar, and steps (G-1) to (G-6) may be repeatedly performed.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a coreless substrate according to a first preferred embodiment of the present invention;

FIGS. 2A to 21 are process cross-sectional views for describing a method of manufacturing the coreless substrate according to the first preferred embodiment of the present invention; and

FIG. 3 is a cross-sectional view of a coreless substrate according to a second preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

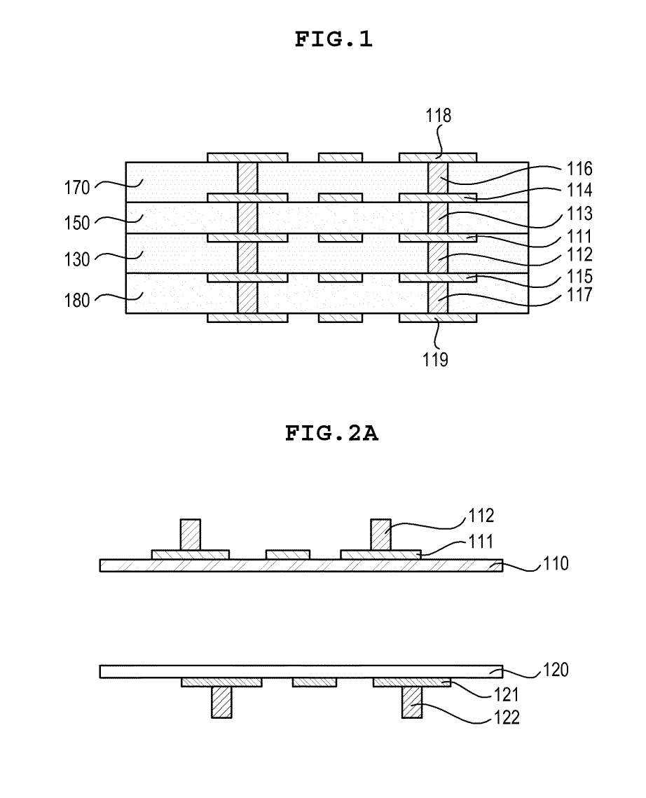

FIG. 1 is a cross-sectional view of a coreless substrate according to a first preferred embodiment of the present invention. Here, the coreless substrate according to the first preferred embodiment of the present invention including, for example, four insulating layers and five circuit layers will be described. Further, the coreless substrate having a multi-layer structure including at least five circuit layers may be used.

As shown in FIG. 1, the coreless substrate according to the first preferred embodiment of the present invention includes a first insulating layer 130, a second insulating layer 150, a third insulating layer 170, and a fourth insulating layer 180 and includes a second circuit layer 114, a third pillar 116, and a top circuit layer 118 that are each symmetrically provided to a first circuit layer 111, a first pillar 112, and a third circuit layer 115 based on the second insulating layer 150.

The coreless substrate according to the first preferred embodiment of the present invention includes four pillars 112, 113, 116, and 117 electrically connecting between the circuit layers provided in each insulating layer from a bottom circuit layer 119 to a top circuit layer 118.

In addition, in the coreless substrate according to the first preferred embodiment of the present invention, a part of the bottom circuit layer 119 or a part of the top circuit layer 118 may be selectively provided with a first surface treating film for improving anti-oxidation and soldering and a second surface treating film for improving connection reliability with external elements by increasing electric conductivity of the bottom circuit layer 119 or the top circuit layer 118.

For example, the first surface treating film may be formed as any one of an organic solderability preservative (OSP) treating film, a black oxide film, and a brown oxide film. In particular, the OSP treating film is divided into an organic solvent type and a water soluble type, wherein the organic solvent type may be formed on a surface of the bottom circuit layer 119 or top circuit layer 118 using roll coating, spray coating, and the like, and the water soluble type may be formed by a dipping method.

In addition, the second surface treating film is, for example, an electroless nickel immersion gold (ENIG) film and may be formed by plating nickel and then plating immersion gold by an electroless plating process.

Therefore, the coreless substrate according to the first preferred embodiment of the present invention may include at least one insulating layer such as the second insulating layer 150 including only the second pillar 113 without including the circuit layer and may be symmetrically provided so as to face the plurality of circuit layers and pillars each other in the plurality of insulating layers that are laminated in a vertical thickness direction based on the insulating layer.

The coreless substrate according to the first preferred embodiment of the present invention is implemented in the buildup layer structure configured of the plurality of insulating layers using the carrier substrate and the dry film and symmetrically includes the plurality of circuit layers and pillars for electrical connection of the buildup layers.

Therefore, the pillars for electrical connection are easily formed in place of the vias formed using laser as in the related art and therefore, the coreless substrate according to the first preferred embodiment of the present invention can save the manufacturing costs and improve the integration of circuits.

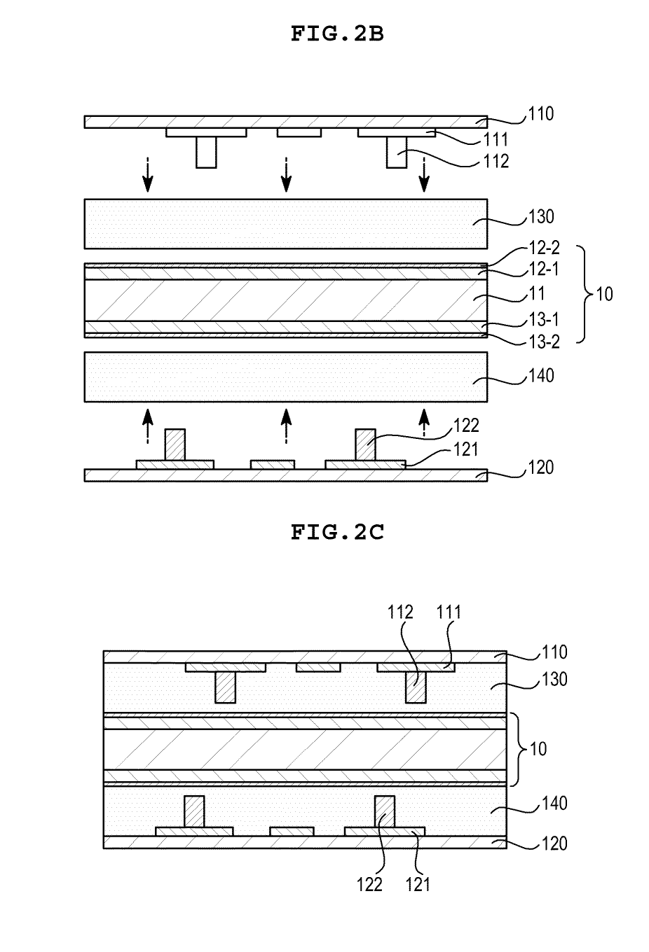

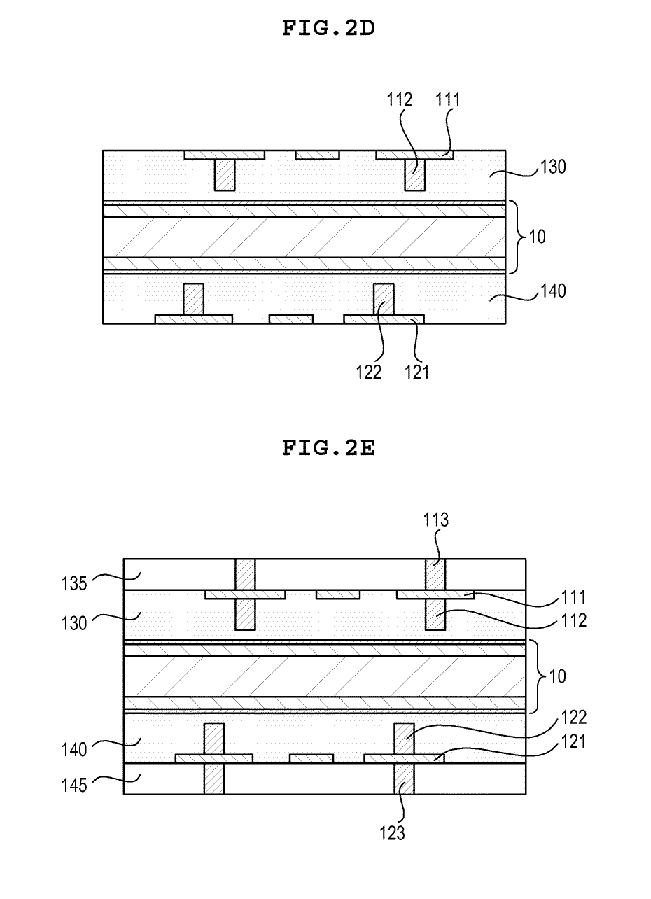

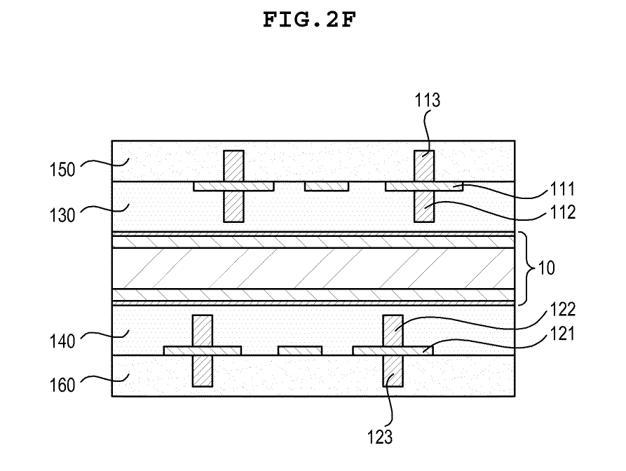

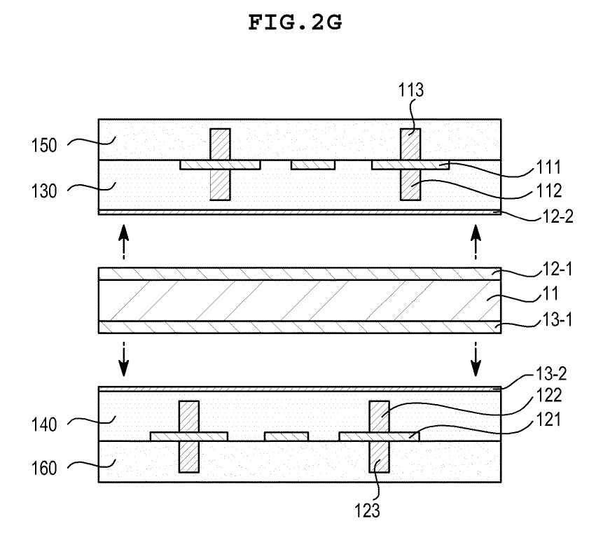

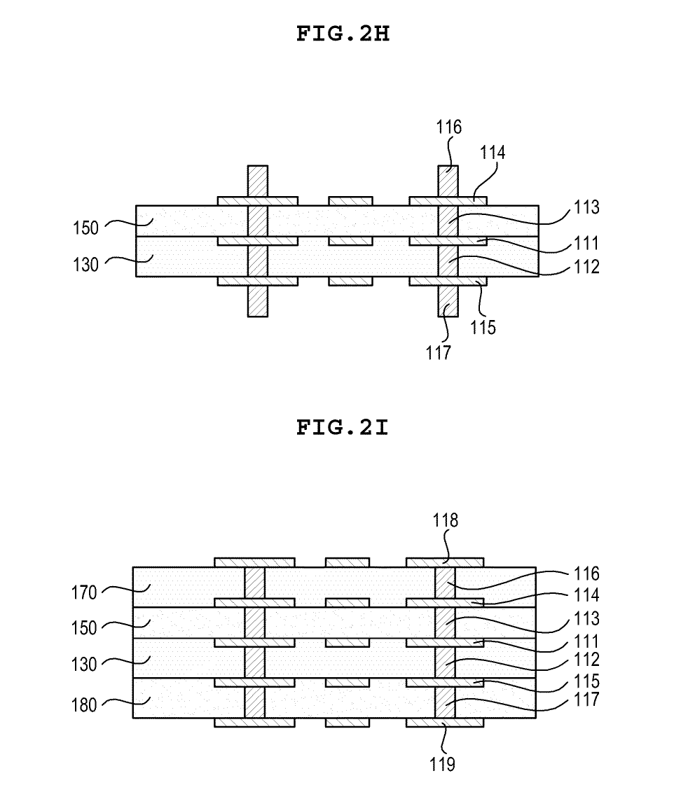

Hereinafter, a method of manufacturing a coreless substrate according to the first preferred embodiment of the present invention will be described with reference to FIGS. 2A to 2I. FIGS. 2A to 2I are process cross-sectional views for describing a method of manufacturing the coreless substrate according to the first preferred embodiment of the present invention.

As shown in FIG. 2A, the method of manufacturing a coreless substrate according to the first preferred embodiment of the present invention forms the circuit layers and the pillars on one surface of an upper barrier plate 110 and a lower barrier plate 120, respectively.

In detail, the upper barrier plate 110 and the lower barrier plate 120 are a metal plate and are used as a support plate for forming the circuit layers and the pillars.

The dry film (not shown) may be laminated on one surface of the upper barrier plate 110 and the lower barrier plate 120 and then, exposed and developed, thereby forming dry film patterns having the plurality of opening parts.

Next, the dry film patterns are filled with copper by CVD, PVD, or electrolytic copper plating and are peeled off, such that the first circuit layer 111 and a first dummy circuit layer 121 are formed on the upper barrier plate 110 and the lower barrier plate 120, respectively.

Next, a surface of the upper barrier plate 110 on which the first circuit layer 111 is provided and a surface of the lower barrier plate 120 on which the first dummy circuit layer 121 is provided are provided with the dry film patterns for forming pillars.

The dry film patterns for forming pillars are also filled with copper by CVD, PVD, or electrolytic copper plating and are peeled off, such that the first pillar 112 and a first dummy pillar 122 are formed on the first circuit layer 111 and the first dummy circuit layer 121, respectively.

Therefore, as shown in FIG. 2A, a structure of a first circuit layer 111 including internal circuits and the upper barrier plate 110 having the first pillar 112 is provided upwardly and a structure of the first dummy circuit layer 121 including internal circuits and the lower barrier plate 120 having the first dummy pillar 122 is provided downwardly.

As shown in FIG. 2B, the structure of the upper barrier plate 110 and the structure of the lower barrier plate 120 are compressed, corresponding the first pillar 112 and the first dummy pillar 122 to the first insulating layer 130 and the first dummy insulating layer 140 each disposed on both surfaces of the carrier substrate 10.

The carrier substrate 10 has, for example, a structure in which two copper clads are laminated on one surface or both surfaces of the insulating plate 11 and serves to support the coreless substrate during the manufacturing process. The preferred embodiment of the present invention describes that the carrier substrate 10 has a structure that two copper clads are disposed on both surfaces of the insulating plate 11, but is not limited thereto and the plurality of copper clads may each be disposed on both surfaces of the insulating plate 11 while having a thickness difference.

In detail, the insulating plate 11 of the carrier substrate 10 is made of, for example, thermosetting resin such as epoxy resin, thermoplastic resin such as polyimide, as resin materials or prepreg formed by impregnating stiffeners such as glass fiber or inorganic filler therein.

For the insulating plate 11, a first upper copper clad 12-1 and a second upper copper clad 12-2 are disposed on an upper surface of the insulating plate 11 and a first lower copper clad 13-1 and a second lower copper clad 13-2 are disposed on a lower surface of the insulating plate 11.

Optionally, a release layer is disposed between the first upper copper clad 12-1 and the second upper copper clad 12-2 or between the first lower copper clad 13-1 and the second lower copper clad 13-2, thereby easily implement the separation of the carrier substrate 10 during the subsequent process.

For example, the release layer is made of an adhesion material of a polymer material selected from a group consisting of borons, silicons, polyethylene terephthalate, polymethylpentene, and a combination thereof, but the preferred embodiment of the present invention is not limited thereto.

As shown in FIG. 2C, a structural portion of the first circuit layer 111 and the first pillar 112 and a structural portion of the first dummy circuit layer 121 and the first dummy pillar 122 are buried in the first insulating layer 130 and the first dummy insulating layer 140, respectively, by compressing the structure of the upper barrier plate 110 and the structure of the lower barrier plate 120.

In this case, the first insulating layer 130 and the first dummy insulating layer 140 are preferably compressed in the uncured environment. To this end, the process of pressing the structure of the upper barrier plate 110 and the structure of the lower barrier plate 120 may also be performed in the state in which the upper barrier plate 110 and the lower barrier plate 120 are heated using a thermocompression press or a thermocompression jig.

Next, as shown in FIG. 2D, a process of removing the upper barrier plate 110 and the lower barrier plate 120 is performed.

Here, the process of removing the upper barrier plate 110 and the lower barrier plate 120 may use an etching method or a chemical mechanical polishing (CMP) method, in particular, use the CMP method capable of obtaining a planarization effect.

As shown in FIG. 2D, the first circuit layer 111 and the first dummy circuit layer 121 are exposed on the flat first insulating layer 130 and first dummy insulating layer 140, respectively, by performing the process of removing the barrier plate 110 and the lower barrier plate 120.

As shown in FIG. 2E, the plurality of second pillars 113 and the plurality of second dummy pillars 123 are partially formed on the first insulating layer 130 and the first dummy insulating layer.

In detail, as shown in FIG. 2E, a dry film pattern 135 for the second pillar and a dry pillar pattern 145 for the second dummy pillar are formed on the flat first insulating layer 130 and the first dummy insulating layer 140, respectively.

The dry film pattern 135 for the second pillar and the dry film pattern 145 for the second dummy pillar are filled with copper by, for example, CVD, PVD, or electrolytic copper plating and the dry film pattern 135 for the second pillar and the dry film pattern 145 for the second dummy pillar are peeled off, such that the plurality of second pillars 113 and the plurality of second dummy pillars 123 are formed on the first circuit layer 111 and the first dummy circuit layer 121, respectively.

As shown in FIG. 2F, the plurality of second pillars 113 and the plurality of second dummy pillars 123 are formed and then, the second insulating layer 150 and the second dummy insulating layer 160 in which the second pillar 113 and the second dummy pillar 123 are each buried are formed.

The second insulating layer 150 and the second dummy insulating layer 160 may be formed by being compressed to the second pillar 113 and the second dummy pillar 123 in the uncured film form by using, for example, a laminator.

In this case, in order to prevent the damage during the compression process, the thickness of the second insulating layer 150 and the second dummy insulating layer 160, respectively, may be formed thicker than the height of the second pillar 113 and the second dummy pillar 123, respectively.

As shown in FIG. 2G, the second insulating layer 150 and the second dummy insulating layer 160 are formed and then, routing is performed on the carrier substrate 10, such that an upper coreless printed circuit precursor including the second upper copper clad 12-2 and a lower coreless printed circuit precursor including a second lower copper clad 13-2 are separated from each other.

In this case, the coreless printed circuit precursor and the lower coreless printed circuit precursor may be more easily separated by the release layer previously disposed between the first upper copper clad 12-1 and the second upper copper clad 12-2 or between the first lower copper clad 13-1 and the second lower copper clad 13-2.

The plurality of insulating layers including the circuit layers and the pillar are laminated on the upper coreless printed circuit precursor and the lower coreless printed circuit precursor, respectively, that are separated from each other as described above, thereby manufacturing the coreless substrate having the multi-layer structure.

For describing the process, the subsequent process will be described with reference to the upper coreless substrate structure including the second pillar 113. Further, the subsequent process to be described below may be identically applied to the lower coreless substrate structure including the second dummy pillar 123.

For the separated upper coreless substrate structure, the second upper copper clad 12-2 is removed and the upper surface of the first filler 112 and the upper surface of the second pillar 133 are exposed to the outside, by performing a process of planarizing the first insulating layer 130 and the second insulating layer 150.

Here, the process of planarizing the first insulating layer 130 and the second insulating layer 150 may use a polishing process using belt-sander, end-mill, or ceramic buff or a chemical mechanical polishing (CMP) process.

Next, as shown in FIG. 2H, the third circuit layer 115 and a fourth pillar 117 are formed on the lower surface of the first insulating layer 130 exposing the first pillar 112 and the second circuit layer 114 and a third pillar 116 are formed on the upper surface of the second insulating layer 150 exposing the second pillar 113.

In detail, the dry films (not shown) are laminated on the lower surface of the first insulating layer 130 and on the upper surface of the second insulating layer 150 and then, subjected to the exposure and development processing, thereby forming the dry film patterns having the plurality of opening parts.

Next, the dry film pattern is filled with copper by CVD, PVD, or electrolytic copper plating and is peeled off, such that the third circuit layer 115 and the second circuit layer 114 are formed on the lower surface of the first insulating layer 130 and the upper surface of the second insulating layer 150, respectively.

Next, the dry film pattern for forming the fourth pillar and the dry film pattern for forming the third pillar are formed on the lower surface of the first insulating layer 130 on which the third circuit layer 115 is disposed and the upper surface of the second insulating layer 150 on which the second circuit layer 114 is disposed.

The dry film pattern for forming the fourth pillar and the dry film pattern for forming the third pillar are filled with copper by CVD, PVD, or electrolytic copper plating and are peeled off, such that the third pillar 116 connected to the second circuit layer 114 and the fourth pillar 117 connected to the third circuit layer 115 are formed.

Therefore, as shown in FIG. 2H, the third circuit layer 115 and the fourth pillar 117 are disposed downwardly from the first insulating layer 130 and the second circuit layer 114 and the third pillar 116 are disposed upwardly from the second insulating layer 150.

As shown in FIG. 2I, after the third pillar 116 and the fourth pillar 117 are formed, the third insulating layer 170 and the fourth insulating layer 180 enclosing the third pillar 116 and the fourth pillar 117, respectively, are formed.

The third insulating layer 170 and the fourth insulating layer 180 are compressed to the third pillar 116 and the fourth pillar 117, respectively, in the uncured film form by using the laminator and may be subjected to the planarization process.

In this case, in order to prevent the damage during the compression process, the thickness of the third insulating layer 170 and the fourth insulating layer 180, respectively, may be compressed to be formed thicker than the height of the third pillar 116 and the fourth pillar 117, respectively.

Thereafter, the top circuit layer 118 and the bottom circuit layer 119 are formed on the third insulating layer 170 and the fourth insulating layer 180 from which the upper surface of the third pillar 116 and the upper surface of the fourth pillar 117 are each exposed by the planarization process. Here, the top circuit layer 118 and the bottom circuit layer 119 may be formed by filling the dry film pattern with copper by CVD, PVD, or electrolytic copper plating, similar to the foregoing method for forming a circuit layer.

After the top circuit layer 118 and the bottom circuit layer 119 are formed, a surface treating film (not shown) may be optionally formed on the top circuit layer 118 and the bottom circuit layer 119.

The surface treating film may be formed of any one of an organic solderability preservative (OSP) treating film, a black oxide film, a brown oxide film, and an electroless plating film.

Here, the OSP treating film is divided into an organic solvent type and a water soluble type, wherein the organic solvent type may be formed by roll coating, spray coating, and the like, and the water soluble type may be formed by a dipping method.

The black oxide film or the brown oxide film may be formed by oxidizing the top circuit layer 118 and the bottom circuit layer 119 made of copper.

In addition, the electroless plating film is, for example, an electroless nickel immersion gold (ENIG) film and may be formed by plating nickel and then plating immersion gold by an electroless plating process.

Further, the surface treating film is not limited the above examples, and therefore, may be formed as hot air solder leveling (HASL) or other surface treating films.

The method of manufacturing a coreless substrate according to the first preferred embodiment of the present invention can mass-produce the coreless substrate without causing warpage due to the use of the carrier substrate 10 and the dry film pattern.

In particular, after the coreless substrate precursor having the multi-layer structure are formed by laminating the plurality of insulating layers including the circuit layers and the pillars in a direction of the upper surface and the lower surface of the carrier substrate 10, that is, both surfaces, the carrier substrate 10 can be separated from each other.

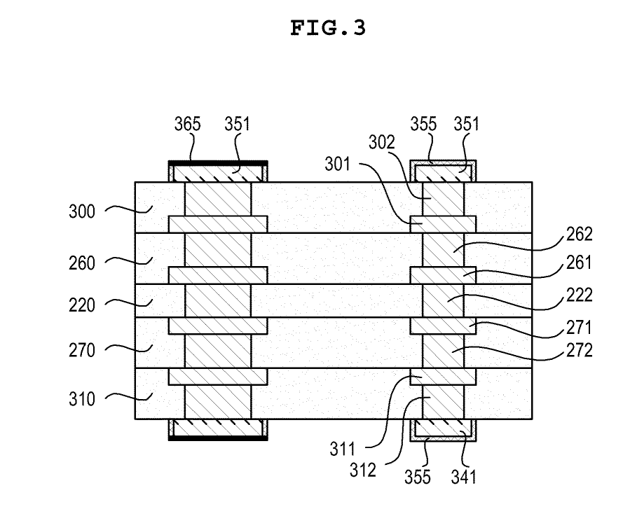

Therefore, in addition to the coreless substrate having four insulating layers 130, 150, 170, and 180 and five circuit layers 111, 114, 115, 118, and 119 shown in FIG. 2I, like a coreless substrate according to a second preferred embodiment of the present invention shown in FIG. 3, the coreless substrate may also be formed in a structure having five insulating layers 220, 260, 270, 300, and 310 and six circuit layers 261, 271, 301, 311, 341, and 351.

Similarly, even in the coreless substrate according to the second preferred embodiment of the present invention shown in FIG. 3, the second upper circuit layer 261 and the second lower circuit layer 271 are symmetrically formed to each other based on the first insulating layer 220.

In particular, the second upper pillar 262, the third upper circuit layer 301, the third upper pillar 302, and the top circuit layer 351 sequentially connected upwardly from the second upper circuit layer 261 each are symmetrically formed to the second lower pillar 272, the third lower circuit layer 311, the third lower pillar 312, and the bottom circuit layer 341 sequentially connected downwardly from the second lower circuit layer 271.

Therefore, the method of manufacturing a coreless substrate according to the preferred embodiment of the present invention forms the coreless printed circuit board precursor having the multi-layer structure in both surfaces using the carrier substrate 10, thereby improving the efficiency of mass-production of the plurality of coreless substrate.

The coreless substrate according to the preferred embodiments of the present invention can be implemented in the buildup layer structure configured of the plurality of insulating layers using the carrier substrate and the dry film and can symmetrically include the plurality of circuit layers and pillars for the electrical connection of the buildup layers, thereby improving the integration of circuits.

Further, the method of manufacturing a coreless substrate according to the preferred embodiment of the present invention can mass-produce the coreless substrate having the multi-layer structure using the carrier substrate and the dry film, thereby improving the efficiency of production.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A coreless substrate, comprising:
a first insulating layer including at least one first pillar;
a plurality of insulating layers laminated in a direction of one surface or both surfaces of the first insulating layer, including at least one circuit layer and at least one another pillar connected to the circuit layer; and
a plurality of outermost circuit layers contacting an outermost pillar disposed on an outermost insulating layer among the plurality of insulating layers.

2. The coreless substrate as set forth in claim 1, wherein the circuit layer is symmetrically disposed in a direction of both surfaces of the first pillar based on the first pillar.

3. The coreless substrate as set forth in claim 1, wherein the circuit layer and another pillar are sequentially repeatedly disposed in an order of the circuit layer contacting the first pillar and the pillar connected to the circuit layer.

4. A method of manufacturing a coreless substrate, the method comprising:
(A) providing at least one barrier plate structure sequentially including a first circuit layer and a first pillar in one direction of a barrier plate;
(B) compressing the barrier plate structure to a first insulating layer disposed on one surface or both surfaces of a carrier substrate, corresponding to the first pillar;
(C) removing the barrier plate and forming a second pillar connected to the first circuit layer;
(D) forming a second insulating layer in which the second pillar is buried;
(E) separating the carrier substrate;
(F) planarizing the first insulating layer and the second insulating layer; and
(G) laminating a plurality of other insulating layers sequentially including another circuit layer and another pillar on an outer surface of the second insulating layer exposing the second pillar or an outer surface of the first insulating layer exposing the first pillar.

5. The method as set forth in claim 4, wherein step (A) includes:
(A-1) laminating a dry film on one surface of the barrier plate and exposing and developing the laminated dry film to form a dry film pattern having a plurality of opening parts;
(A-2) filling the dry film pattern with copper to form a circuit layer;
(A-3) forming a dry film pattern for forming a pillar on a surface of the barrier plate on which the circuit layer is disposed; and
(A-4) filling the dry film pattern for forming a pillar with copper and peeling off the dry film pattern for forming a pillar to form the first pillar.

6. The method as set forth in claim 4, wherein step (C) includes:
(C-1) removing the barrier plate by an etching method or a chemical mechanical polishing method;
(C-2) forming a dry film pattern for a second pillar on the first insulating layer; and
(C-3) filling the dry film pattern for the second pillar with copper and peeling off the dry film pattern for the second pillar to form the second pillar.

7. The method as set forth in claim 4, wherein in step (D), the second insulating layer in an uncured film state is compressed to the second pillar using a laminator.

8. The method as set forth in claim 4, wherein in step (E),
the carrier substrate includes an insulating plate and at least one copper clad laminated on one surface or both surfaces of the insulating plate, and
the carrier substrate is routed so as to be separated.

9. The method as set forth in claim 4, wherein step (G) includes:
(G-1) forming the another circuit layers on the outer surface of the second insulating layer exposing the second pillar or the outer surface of the first insulating layer exposing the first pillar;
(G-2) forming another dry film pattern for forming a pillar on the another circuit layer;
(G-3) filling the another dry film pattern for forming a pillar with copper to form the another filler connected to the another circuit layer;
(G-4) peeling off the another dry film pattern for forming a pillar;
(G-5) laminating the another insulating layer corresponding to the another pillar by using the laminator; and
(G-6) planarzing the another insulating layer so as to expose the another pillar, and steps (G-1) to (G-6) are repeatedly performed.
